(19) United States
(12) Patent Application Publication
(10) Pub. No.: US 2004/0094775 A1
(43) Pub. Date: May 20, 2004

(54) Complementary couple-carry field transistor and the system formed on a substrate

(76) Inventors: Chang Huang, Beijing (CN); Yinghua Yang, Beijing (CN); Dihui Huang, San Jose, CA (US)

Correspondence Address: BIRCH STEWART KOLASCH & BIRCH, PO BOX 747, FALLS CHURCH, VA, 22040-0747, US

(21) Appl. No.: 10/450,619

(22) PCT Filed: Dec. 18, 2001
(86) PCT No.: PCT/CN01/01632

(30) Foreign Application Priority Data
Dec. 18, 2000 (CN) 001354726.3

(51) Int. Cl. H01L 31/0328

(52) U.S. Cl. 257/183

(57) ABSTRACT

The Dual Carrier Field Effect Transistor is characterized by implementing different N-doped and P-doped regions to form channels with narrow cross-sectional area at z=L_{z}. The placement of the source terminal, the drain terminal and the contact terminal is of a two dimensional structure. This invention overcomes the restriction due to lithographic technology and the effective channel length can be reduced to as short as 5 nm even when presently standard semiconductor technology is used. The supply voltage can be decreased to 0.65V, and each transistor can be designed to have 3 to 12 channels to form Dual Carrier Field Effect Transistor complementary inverters and matrix system-on-a-chip with output current as high as 10 amperes. These devices can also be designed to form complicated, high speed and low power dissipation logic circuits as well as high frequency, low power dissipation microwave circuits and system-on-a-chip.

### FIELD OF THE INVENTION

This invention relates to a type of semiconductor two-dimensional Field Effect Transistor and system-on-a-chip thereof, specifically a type of complementary Dual Carrier Field Effect Transistors and system-on-a-chip thereof.

### BACKGROUND OF THE INVENTION

Since the invention of the semiconductor Field Effect Transistor over forty years ago, it has been in wide application in areas such as microwave, microelectronics, semiconductors, computers, communication and home appliances. Current flow is mainly due to the transport of carriers by drift. Known from prior arts, the fabrication of semiconductor Field Effect Transistors is through the diffusion of doping elements into semiconductor materials on an insulating substrate such as silicon-on-insulator (SOI); then by the process of lithographic etching, channels are formed for transistor devices that operate by the Field Effect principle and wherein the channel length has a very dominant effect on the operating performance. Presently, due to the limitation of lithographic equipments, the most advanced target is to form channels as short as 0.07\mathring{3}) or 70 nm; and the lowest supply voltage is around 1 volt. In addition, Field Effect Transistors are usually considered as one-dimensional structures for that at low injection levels, the potential is constant along the z direction and parameters along the other two directions are considered as parasitic parameters; and at high injection levels, the current amplification factor decreases and the potential along the z direction is no longer uniform. Up to now, Field Effect Transistors operate through only one kind of carriers, namely, through either electrons in the N channel transistor or holes in the P channel transistor. In MOS Field Effect Transistors, for example, the working principle is to deplete the majority carriers in the channel region.

### SUMMARY OF THE INVENTION

The main purpose of this invention is to provide a completely new structure as a two dimensional semiconductor Field Effect Transistor. In this structure, the limitation due to regular lithographic technology can be overcome and, by using presently standard semiconductor processing techniques, the effective channel length can be reduced to 5 nm. In the meantime, the supply voltage can be reduced to 0.65 V and the power dissipation can be reduced by a large amount to improve the electrical performance of these two dimensional Field Effect Transistors.

This invention also aims at providing a completely new structure for two-dimensional Field Effect Transistors, which can be combined to form three-dimensional transistors. Each of these three-dimensional transistors can have 3 to 12 channels and they can be combined to implement system-on-a-chip in matrix form with output current up to 10A; moreover, these can be used to form complicated logic circuits, microwave circuits and linear circuits such that the implementation of system-on-a-chip is a much simpler task. The Field Effect Transistors with this new structure include both N-channel Field Effect Transistors and P-channel Field Effect Transistors; and both kind of carriers, i.e. electrons and holes, simultaneously exist to form Dual Carrier Field Effect Transistors. In the normal operation of Dual Carrier Field Effect Transistors, both kinds of carriers exist simultaneously and there is no depletion of majority carriers in the channel region. By this new structure, complementary inverters can be implemented by using both N-channel and P-channel Field Effect Transistors and system-on-a-chip can be implemented by combining multiple Dual Carrier Field Effect Transistors.

The above purpose of this invention is implemented as follows: For a complementary Dual Carrier Field Effect Transistor, two semiconductor homo PN junctions (or hetero PN junctions), either perpendicular or parallel to the surface of the substrate material, are implemented. These are the source junction and the drain junction. Three device terminals are made: these are the source terminal, the drain terminal and the contact terminal. The distance from the contact terminal to the source junction or the drain junction is L_{z}. The distance between the source junction and the drain junction is L_{x,} wherein: different doped regions (such as N, P_{cc}, P_{ch}, P⁺) are implemented either along the direction perpendicular to the substrate or on the same plane of the substrate surface. Under the condition of high injection level and low voltage, a two dimensional potential distribution and electric field distribution, and also a channel with narrow cross-sectional area are formed at z=L_{z}, along the edge between the source junction and the drain junction, close to the contact terminal and are controlled by the contact terminal voltage.

The complementary Dual Carrier Field Effect Transistor, disclosed in this invention, wherein: several layers of semiconductor materials with different impurity doping are implemented successively upon the substrate, or different semiconductor material are implemented in several regions on the same plane of the substrate surface.

The complementary Dual Carrier Field Effect Transistor, disclosed in this invention, wherein: on the insulating substrate, the first layer of semiconductor material forms the N⁺ doped region and an ohmic contact, the drain terminal D, is made in this layer. The second layer of semiconductor material is implemented to form the second doped region, i.e. the channel doped region which includes the channel connection region and a P⁺ heavily doped region on which an ohmic contact, the contact terminal C, is made. The third layer of semiconductor material is implemented to form the N⁺ doped source region where an ohmic contact S, the source terminal, is made.

The complementary Dual Carrier Field Effect Transistor, disclosed in this invention, wherein: in the semiconductor material implemented on top of the insulating substrate, several regions are formed. These respectively are: the P_{c} doped N channel region ch, the P_{cc} doped channel connection region C.C., the P⁺ doped contact region, the N⁺ doped drain region, the N⁺ doped source region. An ohmic contact, the contact terminal C is made on the P⁺ doped contact region. An ohmic contact, the drain terminal D, is made on the N⁺ doped drain region and an ohmic contact, the source terminal S, is made on the N⁺ doped source region.

The above purpose of the present invention can be achieved as follows: a type of Complementary Dual Carrier Field Effect Transistor system-on-a-chip of this invention, wherein: several layers of semiconductor material are implemented on top of a substrate to form complementary inverters including both N channel Field Effect Transistors and P channel Field Effect Transistors, and system-on-a-chip in matrix form with more than two channels.

The complementary Dual Carrier Field Effect Transistor system-on-a-chip, disclosed in this invention, wherein: SOI Dual Carrier Field Effect Transistors are combined with Si MOS, or several SOI vertical Dual Carrier Field Effect Transistors are combined, to form lateral or vertical three-dimensional multiple channel transistor system-on-a-chip.

The complementary Dual Carrier Field Effect Transistor system-on-a-chip disclosed in this invention, wherein: this system-on-a-chip is a complementary Dual Carrier Field Effect Transistor integrated circuit.

To realize the above invention, this application provides the following technical implementation to form P-channel or N-channel Dual Carrier Field Effect Transistors. On the substrate material, two semiconductor PN junctions (homo junction or hetero junction) are formed, either perpendicular or parallel to the surface of the substrate. These are the source junction and the drain junction, and three device terminals—the source terminal, the drain terminal and the contact terminal are made. The distance from the contact terminal to the source junction or the drain junction is L_{z}, the distance between the source junction and the drain junction is Lₓ wherein: in the direction perpendicular to the substrate or in the different regions on the same plane of the substrate material, different doping regions (N, P, P_{cc}, P_{c} or P_{ch}) are formed. Under the condition of high injection level and low voltage, a two dimensional potential distribution and electric field distribution are established, and also a channel with narrow cross-sectional area is formed at z=L_{z}, along the edge between the source junction and the drain junction, close to the contact terminal and controlled by the contact terminal voltage. Hence a Dual Carrier Field Effect Transistor, with two kinds of carriers, is formed and it operates at low voltage and high injection level and is controlled by the voltage at the contact terminal. Its current transport is mainly through drift and its transconductance increases with both the drain terminal voltage and the contact terminal voltage until pinch off, i.e. when the drain voltage is equal to the contact terminal voltage. The effective channel length of this transistor can be decreased to as short as 5 nm and is not restricted by the limitation of lithographic equipments.

The said homojunctions or heterojunctions, for example, are:

| | |
|---|---|
| Si, Si; | Si, SiGe |
| GaAs, GaAs; | GaAs, AlGaAs |
| SiC, SiC; | |

The said PN junctions,

| | |
|---|---|
| Source junction and Drain junction: | N_{d} = 10²⁰ cm⁻³ |
| Channel connection region: | Nₐ = 10¹⁵˜10¹⁹ cm⁻³ |

| | |
|---|---|
| The said Lₓ: | Lₓ = 0.06 ι 2\mathring{3} |
| The said L_{z}: | L_{z} = 0.18 ι 6\mathring{3} |
| The said Vₛ | Vₛ = 0 |
| The said V_{cs} | V_{cs} = 0.3 ι 1.4˜1.8 V |
| The said V_{ds} | V_{ds} = 0.4 ι 2.0 V |
| The said effective channel length: | 5 nm ι 0.2 μ |

Based on the above mentioned basic implementation, the optimum implementation of this invention is as follows: several layers of semiconductor material are implemented in succession on the substrate material, or different semiconductor material are implemented in several regions on the same plane of the substrate. Specifically the several embodiments of optimum implementation are as follows:

1.On and above the insulating substrate, the first layer of semiconductor material forms the N⁺ doped region on which an ohmic contact terminal is made and it is the drain termial D. The second layer of semiconductor material is then formed and it is the second doped region, i.e. the channel doped region and in it the channel connection region is formed. In this second layer, a P⁺ heavily doped region is also formed and on it an ohmic contact terminal, the contact terminal C is made. The third layer of semiconductor material is implemented to form the N doped region on which an ohmic contact terminal is made and it is the source terminal S.

2 On the insulating substrate, a layer of semiconductor material like Si etc. is implemented with different regions along the same plane. These are the P_{c} doped channel region Ch, the P_{cc} doped channel connection region C.C., the P⁺ doped contact region, the N⁺ doped drain region, the N doped source region. An ohmic contact, the contact terminal C, is made on the P⁺ doped connection region. An ohmic contact terminal, the drain terminal D, is made on the N doped drain region. An ohmic contact, the source terminal S, is made on the N⁺ doped source region.

Included also in this invention are the complementary inverter which has both an N channel Field Effect Transistor and a P channel Field Effect Transistor; and the systemon-a-chip in a matrix form with more than two channels.

This invention provides a type of semiconductor Field Effect Transistor with a completely new structure. With this new structure, the Field Effect Transistor in which the transport of current is mainly through the drift of carriers can be fabricated by presently standard semiconductor technology but is not restricted by the limitation of readily available lithographic equipments. The effective channel length can be decreased to as short as 5 nm and the supply voltage can be reduced to as low as 0.65v. In this new structure, the current in the channel is not due to injection across the whole cross-sectional surface and therefore the power consumption is greatly reduced and its electrical performance is improved. Adopting this structure, each transistor can have 3 to 12 channels to form three-dimensional transistors and system-on-a-chip in matrix form. The output current can be as high as 10A.Transistors with this new structure can be used to form complicated logic circuits, microwave circuits and linear circuits such that the implementation of system-on-a-chip becomes a rather easy task. Field Effect Transistors that adopt this new structure include both N channel Field Effect Transistors and P Channel Field Effect Transistors. In these two kinds of Field Effect Transistors, both kind of carriers, i.e. electrons and holes simultaneously exist. Both kinds of carriers contribute to the proper functioning of these Field Effect Transistors to form Dual Carrier Field Effect Transistors and there is no depletion of carriers in their channel regions. This new structure also includes Complementary inverters with both N channel Field Effect Transistors and P channel Field Effect Transistors.

### BRIEF DESCRIPTION OF THE ACCOMPANYING DRAWINGS

Further explanation of embodiments is provided along with attached figures.

FIG. 1. is a structural schematic view of a single material N channel vertical Dual Carrier Field Effect Transistor in embodiment 1.

FIG. 2. is a structural schematic view of a hetero-junction N channel vertical Dual Carrier Field Effect Transistor in embodiment 2.

FIG. 3. is a structural schematic view of an N channel lateral Dual Carrier Field Effect Transistor on Insulator Material in embodiment 3.

FIG. 4. is a structural schematic view of an N channel lateral Dual Carrier Field Effect Transistor on intrinsic substrate in embodiment 4.

FIG. 5. is a diagram illustrating the output characteristics of N channel lateral Dual Carrier Field Effect Transistors in embodiments 1, 2, 3, 4.

FIG. 6 is a structural schematic view of the lateral three-dimensional Dual Carrier Field Effect Transistor. It can be seen that embodiment 5 is the combination of SOI N channel lateral Dual Carrier Field Effect Transistor described in embodiment 3 with an SOI MOS Transistor.

FIG. 7 is a diagram illustrating the Dynamic Threshold Voltage Characteristics of embodiment 5.

FIG. 8 is the circuit diagram of a Complementary lateral dual Carrier Field Effect Transistor inverter operating at a supply voltage of 0.65v.

FIG. 9 is the schematic view of a system-on-a-chip with N channel lateral Dual Carrier Field Effect Transistors in matrix form.

FIG. 10 is the schematic view of a vertical two-dimensional Field Effect Transistor with 8 channels, namely, a combination of eight N channel vertical Dual Carrier Field Effect Transistors in embodiment 6.

FIG. 11 is a schematic view of a vertical Dual Carrier Field Effect Transistor system-on-a-chip with 48 N channels; that is, a combination of 48 N channel vertical Dual Carrier Field Effect transistors in matrix form, given in embodiment 7.

FIG. 12 is a structural schematic view of complementary inverters constructed with heterojunction vertical Dual Carrier Field Effect Transistors on a Silicon Oxide substrate in embodiment 8.

FIG. 13 is a structural schematic view of a NAND gate constructed with vertical, complementary Dual Carrier Field Effect Transistors (heterojunction) in embodiment 9.

FIG. 14 is a structural schematic view of inverters constructed with vertical, complementary Dual Carrier Field Effect Transistors (both homojunction and heterojunction) on an intrinsic GaAs substrate in embodiment 10.

### DETAILED DESCRIPTION OF PREFERRED EMBODIMENTS

### EMBODIMENT 1

Single Material N Channel Vertical Dual Carrier Field Effect Transistor.

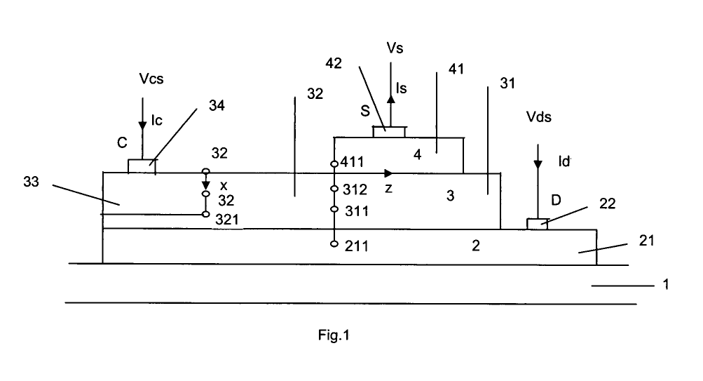

Referring to FIG. 1 (The labels 1,2 etc. in the figure are all numerals of FIG. 1, therefore 1 is actually 1-1, 2 is actually 1-2, . . . etc.): The first layer of semiconductor material 1-2 (for example Si, GaAS, SiC etc.) is implemented on the insulating substrate 1-1 to form the N⁺ doped region 1-21; 1-22 is the ohmic contact terminal, that is the drain terminal D. 1-3 is the second layer of semiconductor material (for example Si, GaAS, SiC etc.) and forms the second doped region 1-31, that is the channel doped region. 1-32 is P_{cc} doped region of the second layer, that is, the channel connection region. 1-33 is the P⁺ heavily doped region of the second layer of semiconductor material. 1-211 is the edge (x=Lₓ+x_{nd}, z=L_{z}) of the space charge region of the N⁺P_{c} (1-21, 1-31) drain junction in the N⁺ region. 1-311 is the edge (x=Lₓ−x_{pd}, z=L_{z}) of the space charge of the N⁺P_{c} (1-21, 1-31) drain junction in P_{c} region. 1-321 is the point corresponding to 1-311 and is at (x=Lₓ−x_{pd}, Z=0). 1-34 is the ohmic contact terminal, that is, the contact terminal C. 1-4 is the third layer of semiconductor material. 1-41 is the N⁺ doped region and 1-42 is the ohmic contact terminal, that is the source terminal S. 1-312 is the edge (x=xₚₛ, z=L_{z}) of the space charge region of the P_{c}N⁺ (1-31, 1-41) source junction in the P_{c} region. 1-411 is the edge (x=−xₙₛ, z=L_{z}) of the space charge region of the P_{c}N⁺ source junction in the N⁺ region. Point 1-322 corresponds to 1-312 and is at (x=xₚₛ, z=0). 1-323 is at the origin (x=0, z=0) of the co-ordinates. The voltages at the contact terminal, the source terminal and the drain terminal are V_{cs}, Vₛ and V_{ds} respectively. Usually we set Vₛ=0 and the terminal currents are respectively I_{c}, Iₛ and I_{d}. Positive current direction is as indicated by the arrow head in the figure.

### EMBODIMENT 2

Heterojunction N Channel Vertical Dual Carrier Field Effect Transistor. The structure is basically similar to Embodiment 1, but the fabrication process and the device performance are different.

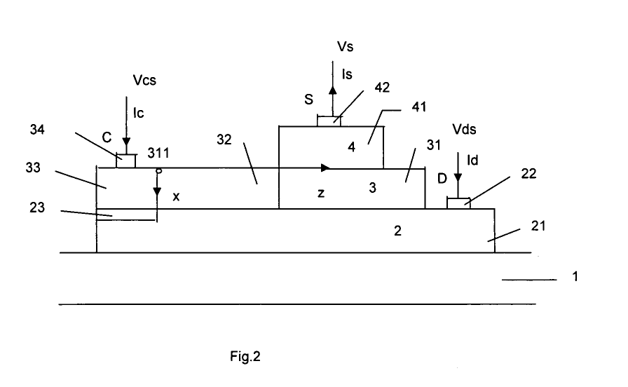

Referring to FIG. 2 ( the labels 1,2, etc. in the figure are all numerals of FIG. 2, therefore 1 is actually 2-1, 2 is actually 2-2 . . . etc.): the first layer of semiconductor material 2-2 (e.g. Si, GaAS etc.) is implemented on the insulating substrate 2-1 to form the N⁺ doped region 2-21. 2-22 is the ohmic contact terminal of the first layer of semiconductor, that is the drain terminal D. 2-23 is the P doped region of the first layer of semiconductor material. 2-3 is the second layer of semiconductor material (e.g. SiGe, AlGaAs etc.), and, in the second layer, the P_{ch} doped region 2-31 is the N channel region ch. 2-32 is the P_{cc} doped region of the second layer, i.e. the channel connection region CC. 2-33 is the P⁺ heavily doped region of the second layer. 2-34 is the ohmic contact terminal for the second semiconductor layer, that is, the contact terminal C. 2-311 is the co-ordinate origin (x=0, z=0). 2-4 is the third layer of semiconductor material (e.g. Si, GaAs etc.). 2-41 is the N⁺ doped region, that is, the source region S. 2-42 is the ohmic contact terminal of the third layer of semiconductor material, that is, the source terminal S. The terminal voltages and terminal currents at the contact terminal, the source terminal and the drain terminal are the same as in embodiment 1. Positive current direction is as indicated by the arrowheads in the figure.

### EMBODIMENT 3

N Channel Lateral Dual Carrier Field Effect Transistor on Insulator Substrate.

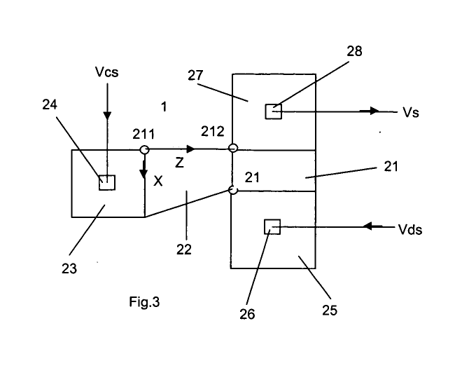

Referring to FIG. 3 (The labels 1,2, etc. in the figure are all numerals of FIG. 3, therefore 1 is actually 3-1, 2 is actually 3-2, . . . etc.): implemented on insulating substrate 3-1 is the semiconductor material 3-2 ( e.g. Si). 3-21 is the P_{c} doped N channel region ch. 3-22 is the P_{cc} doped channel connection region C.C. 3-23 is the P⁺ doped contact region. 3-24 is the ohmic contact terminal for 3-23, that is, the contact terminal C. 3-25 is the N⁺ doped drain region, 3-26 is the ohmic contact terminal for the drain region, that is, the drain terminal D. 3-27 is the N⁺ doped source region, 3-28 is the ohmic contact terminal for region 3-27, that is, the source terminal S. 3-211 is the coordinate origin (x=0, z=0). 3-212 (x=0, z=L_{z}) is at the edge of the N⁺P_{ch} junction formed by the N⁺ region (3-27) and the P_{ch} region (3-21), close to the contact region. 3-213 (x=Lₓ, z=L_{z}) is at the edge of the P_{ch}N⁺ junction formed by the channel region (3-21) and the drain region (3-25). Terminal voltages and terminal currents are the same as that given in embodiment 2. Positive direction of the terminal currents is as shown by the arrowheads in FIG. 3.

### EMBODIMENT 4

N Channel Lateral Dual Carrier Field Effect Transistor on Intrinsic Semiconductor Substrate, which is basically the same as implementation example 3, however, the device fabrication process and device performance are different.

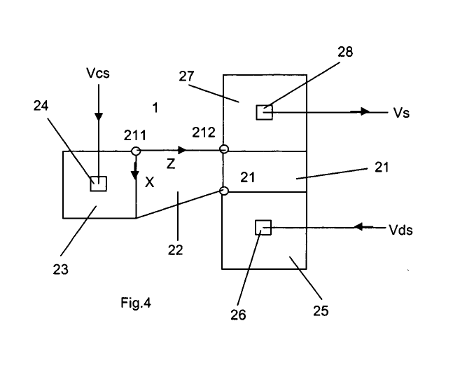

Referring to FIG. 4 (The labels 1,2, etc. in the figure are all numerals of FIG. 4, therefore 1 is actually 4-1, 2 is actually 4-2, . . . etc.): implemented on the intrinsic semiconductor substrate 4-1 ( for example intrinsic Si) is the doped semiconductor material 4-2 such as Si etc. 4-21 is the P_{ch} doped channel region ch. 4-22 is the P_{cc} doped channel connection region c.c. 4-23 is the P⁺ doped contact region. 4-24 is the ohmic contact terminal for region 4-23, that is, the contact terminal C. 4-25 is the N⁺ doped drain region, 4-26 is the ohmic contact terminal for region 4-25, that is, the drain terminal D. 4-27 is the N⁺ doped source region, 4-28 is the ohmic contact terminal for region 4-27, that is, the source terminal S. 4-211 is the co-ordinate origin (x=0, z=0). 4-212 (x=0, z=L_{z}) is at the edge of the N⁺P_{ch} junction formed by the N⁺ region (4-27) and the P_{ch} region (4-21), near to the contact region. 4-213, 4-212 are at the edge of the regions 4-21 and 4-25 and regions 4-21 and 4-27 ( N⁺P_{ch} junction); both near to the contact region. The terminal voltages and terminal currents are similar to embodiment 3. The positive direction of the terminal currents is as shown by the arrowheads in FIG. 4.

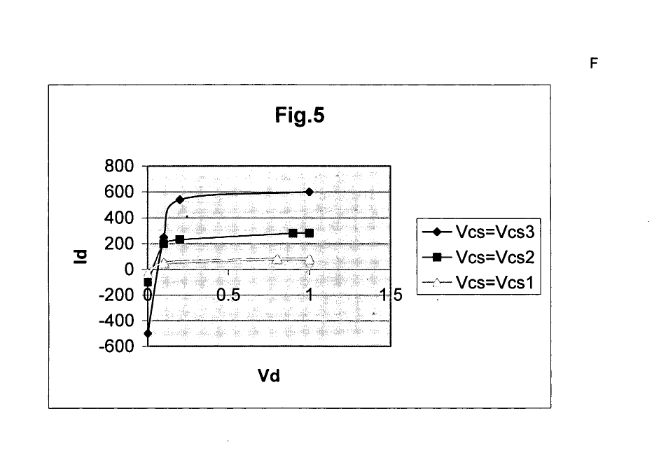

It is to be noted that P channel Dual Carrier Field Effect Transistors can be obtained by exchanging P-doped material with N-doped material and vice versa in FIG. 3. According to theoretical calculations and experimental verification, the output characteristics of Dual Carrier Field Effect Transistors are as shown in FIG. 5. Take the Si Dual Carrier Field Effect Transistor in embodiment 3, as an example, the transport of dual carriers in the two dimensional device structure of the Si Dual Carrier Field Effect Transistor is described by nine variables: [symbol] (x,z), p(x,z), n(x,z), Eₓ(x,z), E_{z}(x,z), jₚₓ(x,z), jₙₓ(x,z), j_{pz}(x,z), j_{nz}(x,z) and nine partial differential equations.

Calculated results show that

$$When 2 \frac{kT}{q} ln \frac{{N}_{A}}{{n}_{i}} π ( {V}_{DS} = {V}_{CS} ) π 1 V$$

$$and {V}_{s} = 0 , \\ \begin{matrix} {V}_{z} = ( x = {x}_{ps} , z = 0 ) - ( x = {x}_{ps} , z = {L}_{z} ) \\ = {V}_{x} = ( x = {L}_{x} - {x}_{pp} , z = {L}_{z} ) - ( x = {x}_{p} , z = {L}_{z} ) \\ {E}_{x} = \frac{Δ {V}_{z}}{{L}_{x} - {X}_{ps} - {X}_{pd}} = \frac{Δ {V}_{x}}{{L}_{x} - {X}_{ps} - {X}_{pd}}\end{matrix}$$

Where

Lₓ is the distance between the source junction and the drain junction

L_{z} is the distance from the contact terminal to the edge of the source junction

xₚₛ, x_{pd} are the thickness of the space charge region on the p side of the source junction and on the p side of the drain junction

xₙₛ, x_{nd} are the thickness of the space charge region on the n side of the source region and on the n side of the drain region

The drift of holes and electrons is due to the field Eₓ, and as a result, the drain current I_{D} flows from the drain junction to the source junction to form the N channel current, as shown at the pinch off point in FIG. 5.

The characteristics of Dual Carrier Field Effect Transistors are described by the transconductance gₘ as given below:

$$d . c . transconductance = {g}_{md . c .} = \frac{{I}_{D}}{{V}_{DS}}$$

$$a . c . transconductanc = {g}_{ma . c .} = \frac{\partial {I}_{D}}{\partial {V}_{DS}}$$

With proper design, and based on presently standard semiconductor technology, the effective channel length

L_{eff}=Lₓ−xₚₛ−x_{pd}

are as follows:

| | |
|---|---|
| Si Vertical Dual Carrier Field Effect Transistor: | L_{eff} = 5 nm |
| Si—SiGe Vertical Dual Carrier Field Effect Transistor: | L_{eff} = 5 nm |
| SOl Lateral Dual Carrier Field Effect Transistor: | L_{eff} = 10 nm |
| Intrinsic Lateral Dual Carrier Field Effect Transistor: | L_{eff} = 10 nm |

The cutoff frequency and transit time of these four kinds of transistors are as follows:

$${f}_{T} = \frac{μΔ {V}_{z}}{2 π ( {L}_{eff} )} > 6000 Ghz$$

$${τ}_{T} = \frac{4 {L}_{eff}}{3 μΔ {V}_{z}} < 0.05 ps$$

### EMBODIMENT 5

The Combination of SOI Lateral Dual Carrier Field Effect Transistors with MOS—a three dimensional device.

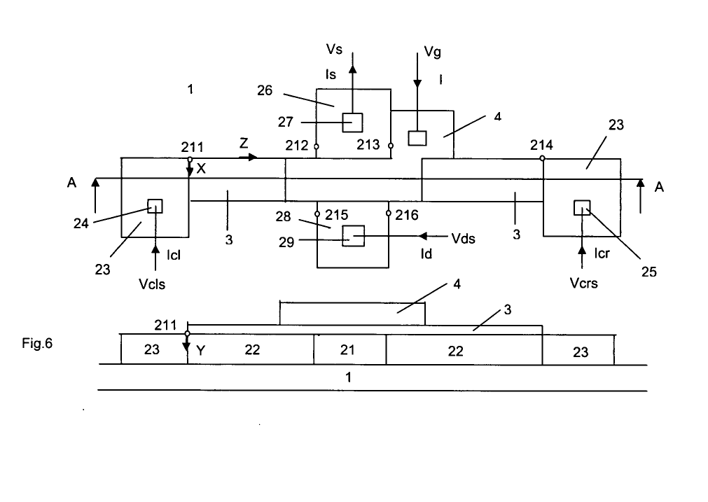

Referring to FIG. 6 (label interpretation is the same as in preceding embodiments): x is the channel direction, z is the direction from the contact terminal to the channel region, y is the direction perpendicular to the gate oxide of the MOSFET. Tsi is the thickness of the silicon material. The first layer of semiconductor material 6-2 (e.g. Si) is implemented on the insulator substrate 6-1 (e.g. SiO₂). 6-21 is the P_{ch} doped semiconductor region, i.e. the channel region. 6-22 is the P_{cc} doped semiconductor channel connection region. 6-23 is the P⁺ doped semiconductor contact region. 6-24 is the right ohmic contact terminal for region 6-23 that is the right contact terminal Cr. 6-25 is the left ohmic contact terminal for region 6-23, that is the left contact terminal Cl. 6-26 is the N⁺ doped source region. 6-27 is ohmic contact terminal for region 6-26, that is the source terminal S. 6-28 is the N⁺ doped drain region. 6-29 is the ohmic contact terminal for region 6-28, that is the drain terminal D. 6-3 is the SiO₂ insulating layer for the gate. 6-4 is the gate polysilicon. 6-41 is the contact terminal for the gate, that is, the gate terminal G. 6-211 is the co-ordinate origin (x=0, y=0, z=0). 6-212 (x=−xₙ, y=0, z=L_{zl}) is at the edge of the space charge region in the N⁺ source region of the PN⁺ junction, region 6-21 and region 6-26, close to the left contact region. 6-213 (x=−xₙ, y=0, z=L_{zl}+W_{z}) is at the edge of the space charge region in the N⁺ source region of the PN⁺ junction, region 6-21 and region 6-26, close to the right contact region. 6-214 (x=0, y=0, z=L_{zl}+W_{z}+L_{zr}) is at the edge of the right contact region. 6-215 (x=Lₓ+xₙ, y=0, z=L_{zl}) is at the edge of the space charge region in the N⁺ drain region of the PN⁺ junction, region 6-21 and region 6-18, close to the left contact region. 6-216 (x=Lₓ+xₙ, y=0, z=L_{zl}+W_{z}) is at the edge of the space charge region in the N⁺ drain region of the PN⁺ junction, region 6-21 and region 6-28, close to the right contact region. 6-217 (x=6x/2, y=Tₛᵢ, z=0 ) is the point at the interface of region 6-3 and region 6-2. 6-218 (x=Lₓ/2, y=0, z=0) is the point at the interface of region 6-1 and region 6-2. This Three Dimensional Field Effect Transistor has two Dual Carrier Effect Transistor channels and one MOS channel, that is three channels in total. Because the channel current flows in the direction parallel to the surface of the semiconductor material, it is called Lateral Three Dimensional Field Effect Transistor. If a back gate is implemented, two Dual Carrier channels together with two MOS channels can be obtained. If the back terminal is implemented in the Dual Carrier form, three Dual Carrier channels and one MOS channel can be obtained. There are twelve variables for three-dimensional analysis. These are:

[symbol] (x,y,z), p(x,y,z), n(x,y,z), Eₓ(x,y,z), E_{y}(x,y,z), E_{z}(x,y,z),

Jₚₓ(x,y,z), J_{py}(x,y,z), J_{pz}(x,y,z), Jₙₓ(x,y,z), J_{ny}(x,y,z), J_{nz}(x,y,z)

The solution for these 12 variables can be obtained by 12 partial differential equations; that is the Poisson's equation, 3 electric field equations, 6 current density equations, and two current continuity equations.

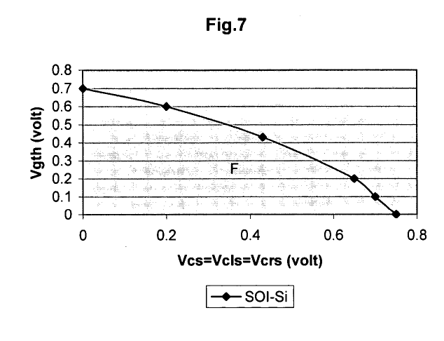

Three dimensional analysis shows that the dynamic threshold voltage characteristics of Three Dimensional Dual Carrier Field Effect Transistor is as shown in FIG. 7, where it is assumed that V_{CLS}=V_{CRS}=V_{CS}. This characteristics has also been experimentally verified. The dynamic threshold voltage characteristics of Si material, as shown in FIG. 7, has been predicted through theoretical analysis and verified by experimental results.

When

$${V}_{cs} > 2 \frac{kT}{q} ln \frac{{N}_{A}}{{n}_{i}} ,$$

the Dual Carrier Field Effect Transistor in the Three Dimensional Field Effect Transistor plays the dominant role; this has not yet been theoretically analyzed or measured experimentally previously. Utilizing the property of dynamic threshold voltage, the power supply voltage can be reduced to less than 0.65v.

When N₁₁=N₁₃=N₁₅=N₂₁=N₂₃=N₂₅=S

N₁₂=N₁₄=N₂₂=N₂₄=D (1)

and Cₙₘ and Gₙₘ are inputs, D is the output, then the output function is

f=(C₁₁+G₁₁+C₂₁+C₁₂+G₁₂+C₂₂+^{. . . . . .} +C₃₄)

there are in total 16 Dual Carrier channels and 8 MOS channels, and this is a NOR gate with 20 inputs.

When N₁₁=N₂₁=S, N₁₅=N₂₅=D,

Cₙₘ, Gₙₘ are inputs, D is the output, (2)

then the output function is

f=(C₁₁+G₁₁+C₂₁)·(C₁₂+G₁₂+C₂₂)·(C₁₃+G₁₃+C₃₃)·

(C₁₄+G₁₄+C₂₄)·(C₂₁+G₂₁+C₃₁)·(C₂₂+G₂₂+C₃₂)·

(C₂₃+G₂₃+C₃₃)·(C₂₄+G₂₄+C₃₄)

Other output functions can also be obtained corresponding to other input combinations.

### EMBODIMENT 6, 8

Channel Vertical N Channel Three Dimensional Field Effect Transistor.

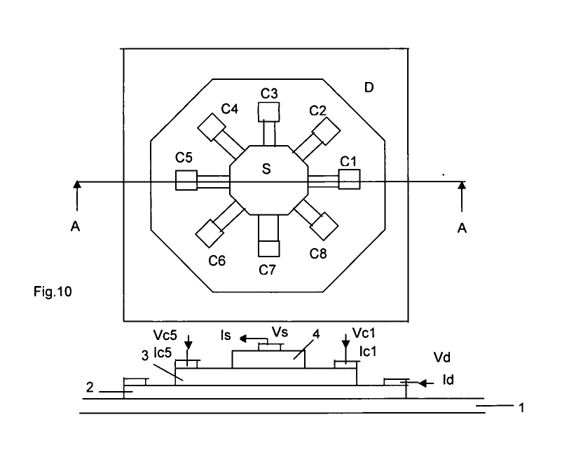

This is also called homo material or hetero junction Dual Carrier Field Effect Transistor. Referring to FIG. 10 (label interpretation is the same as in above embodiments): the basic structure is similar to that shown in the preceding embodiments. 10-3 is the second layer of semiconductor material (SiO₂ . . . ). 10-4 is the third layer of semiconductor(SiO₂ . . . ).

### EMBODIMENT 7

A Combination of 6 Matrix Form 8 Channels Vertical Three Dimensional Field Effect Transistor.

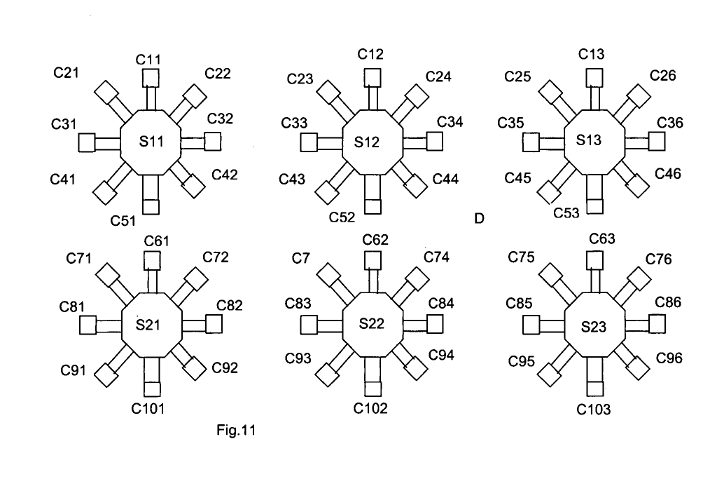

This can also be called 48 N Channel Vertical Dual Carrier Field Effect Transistor system-on-a-chip, refer to FIG. 11 (structure and label interpretation are the same as in the above embodiments).

### EMBODIMENT 8

Complementary Vertical Dual Carrier Field Effect Transistor Inverter with single material and Si-SiGe Heterojunction on SiO₂ Substrate.

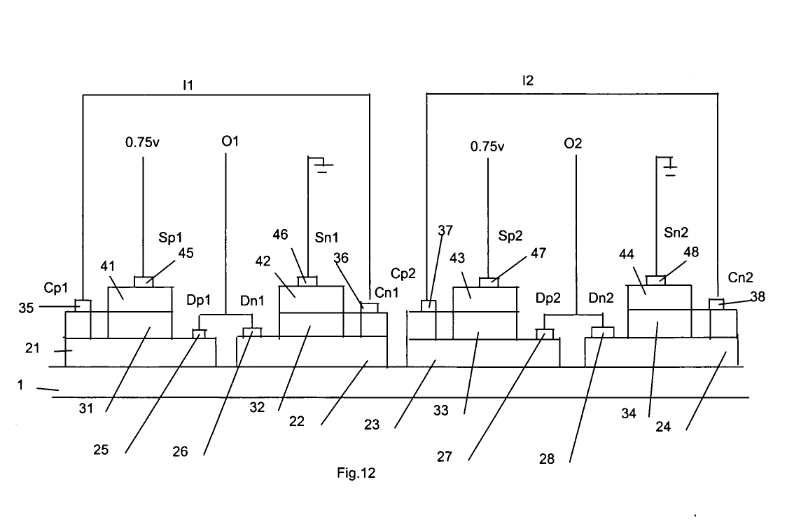

Refer to FIG. 12 (label interpretation is the same as in preceding embodiments). On the silicon dioxide substrate 12-1, the first layer of P⁺-doped semiconductor material 1 (e.g. Si), 12-21, is implemented. 12-22 is the first layer of N⁺-doped semiconductor material 1 (e.g. Si). 12-23 is the first layer of P⁺-doped semiconductor material 1 ( e.g. Si), 12-24 is the first layer of N⁺-doped semiconductor material 1 ( e.g. Si). 12-25 is the ohmic contact terminal for 12-21, that is the drain terminal D_{p1.} 12-26 is the ohmic contact terminal for 12-22, that is the drain terminal Dₙ₁. 12-27 is the ohmic contact terminal for 12-23, that is the drain terminal D_{p2.} 12-28 is the ohmic contact terminal for 12-24, that is the drain terminal Dₙ₂. 12-31 is the N_{ch}-doped second layer of semiconductor material 1 (e.g. Si), 12-32 is the P_{ch}-doped second layer of semiconductor material 1 ( e.g. Si), 12-33 is the N_{ch}-doped second layer of semiconductor material 2 ( e.g. SiGe), 12-34 is the second layer of doped semiconductor material 2 (e.g. SiGe). 12-35 is the contact terminal Cₚ₁ for controlling region 12-31, 12-36 is the contact terminal Cₙ₁ for controlling region 12-32, 12-37 is the contact terminal Cₚ₂ for controlling region 12-33, 12-38 is the contact terminal Cₙ₂ for controlling region 12-34. 12-41 is the P⁺-doped third layer of semiconductor material 1 (e.g. Si). 12-42 is the N⁺-doped third layer of semiconductor material 1 (e.g. Si), 12-43 is the P⁺-doped third layer of semiconductor material 1 (e.g. Si), 12-44 is the N⁺-doped third layer of semiconductor material 1 (e.g. Si). 12-45 is the ohmic contact terminal for region 12-41, that is the source terminal Sₚ₁. 12-46 is the ohmic contact terminal for region 12-42, that is the source terminal S_{n1.} 12-47 is the ohmic contact terminal for region 12-43, that is the source terminal Sₚ₂. 12-48 is the ohmic contact terminal for region 12-44, that is the source terminal S_{n2.}

### EMBODIMENT 9

NAND Gate of Complementary Heterojunction Vertical Dual Carrier Field Effect Transistors on Silicon Dioxide Substrate.

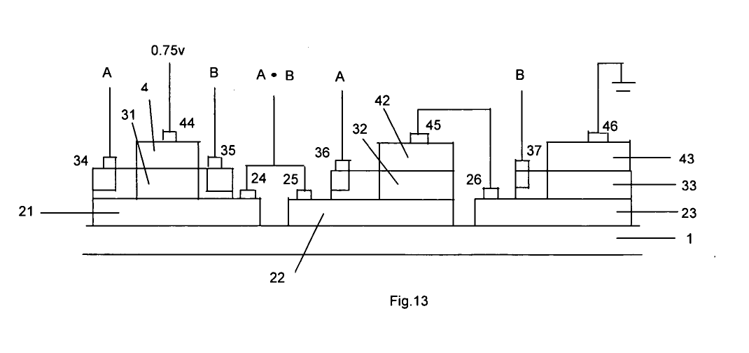

Referring to FIG. 13 (label interpretation as in above embodiments): implemented on the the silicon dioxide insulating substrate 13-1, 13-21 is the P⁺-doped first layer of semiconductor material 1 (Si), 13-22 is the N⁺-doped first layer of semiconductor material 1 (Si), 13-23 is the N⁺-doped first layer of semiconductor material 1 (Si). 13-24 is the ohmic contact terminal for region 13-21, that is the drain terminal D_{P1}. 13-25 is the ohmic contact terminal for region 13-22, that is the drain terminal D_{N1}. 13-26 is the ohmic contact terminal for region 13-23, that is the drain terminal D_{N2}. 13-31 is the N-doped second layer of semiconductor material 1 (Si). 13-32 is the P-doped second layer of semiconductor material 2 (SiGe). 13-33 is the P-doped second layer of semiconductor material 2 (SiGe). 13-34 is the left contact terminal C_{P1} for controlling the channel region 13-31. 13-35 is the right contact terminal C_{P2} for controlling the channel region 13-31. 13-36 is the contact terminal C_{N1} for controlling the channel region 13-32. 13-37 is the contact terminal C_{N2} for controlling the channel region 13-33. 13-41 is the P⁺ doped third layer of semiconductor material 1 (Si), 13-42 is the N⁺-doped third layer of semiconductor material 1 (Si), 13-43 is the N⁺-doped third layer of semiconductor material 1 (Si), 13-44 is the ohmic contact terminal for region 13-41, that is terminal S_{P}. 13-45 is the ohmic contact terminal for region 13-42, that is terminal S_{N1}. 13-46 is the ohmic contact terminal for region 1-43, that is terminal S_{N2}.

### EMBODIMENT 10

Complementary Vertical Dual Carrier Field Effect Transistor Inverter with GaAs homojunction and GaAs-AlGaAs Heterojunction on intrinsic GaAs substrate.

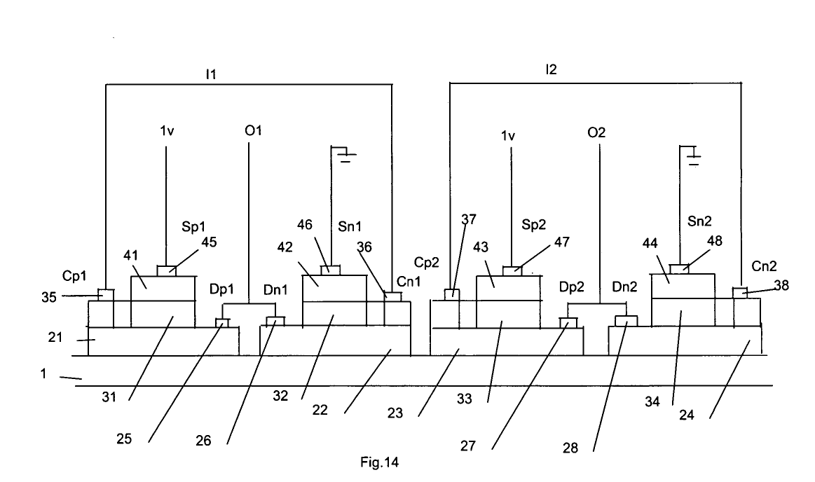

Refer to FIG. 14 (label interpretation similar to preceding embodiments): on the intrinsic GaAs substrate 14-1, 14-21 is the P⁺-doped first layer of semiconductor material 1 (GaAs), 14-22 is the N⁺-doped first layer of semiconductor material 1 (GaAs), 14-23 is the P⁺-doped first layer of semiconductor material 1 (GaAs), 14-24 is the N⁺-doped first layer of semiconductor material 1 (GaAs). 14-25 is the ohmic contact terminal for region 14-21, that is, the drain terminal D_{P1}. 14-26 is the ohmic contact terminal for region 14-22, that is, the drain terminal D_{N1}. 14-27 is the ohmic contact terminal for region 14-23, that is, the drain terminal D_{P2}. 14-28 is the ohmic contact terminal for region 14-24, that is, the drain terminal D_{N2}. 14-31 is the N-doped second layer of semiconductor material 1 (GaAs), 14-32 is the P-doped second layer of semiconductor material 1 (GaAs), 14-33 is the N-doped second layer of semiconductor material 2 (AlGaAs), 14-34 is the P-doped second layer of semiconductor material 2 (AlGaAs). 14-35 is the contact terminal C_{P1} for control of the channel region 14-31, 14-36 is the contact terminal C_{N1} for control of the channel region 14-32, 14-37 is the contact terminal C_{P2} for the control of the channel region 14-33, 14-38 is the contact terminal C_{N2} for control of the channel region 14-34. 14-41 is the P⁺-doped third layer of semiconductor material 1 (GaAs), 14-42 is the N⁺ doped third layer of semiconductor material 1 GaAs), 14-43 is the P⁺-doped third layer of semiconductor material 1 (GaAs), 14-44 is the N⁺-doped third layer of semiconductor material 1 (GaAs), 14-45 is the ohmic contact terminal for region 14-41, that is, terminal S_{P1}. 14-46 is the ohmic contact terminal for region 14-42, that is, terminal S_{N1}. 14-47 is the ohmic contact terminal for region 14-43, that is, terminal S_{P2}. 14-48 is the ohmic contact terminal for region 14-44, that is, source terminal S_{N2}.

The fabrication process of these two structures are respectively compatible with that of SOI, BJT, HBT, CMOS and III-VI compounds such as AlGaAs-GaAs heterojunction or homojunction BJT, HBT, these can respectively be used to form system-on-a-chip on SOI or intrinsic GaAs substrate. These are Dual Carrier Field Effect Transistor system-on-a-chip on SOI substrate and system-on-a-chip with homojunction and heterojunction Dual Carrier Field Effect transistors on intrinsic GaAs substrate.

### EMBODIMENT 11

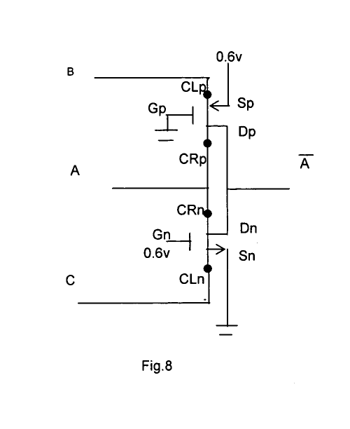

Referring to FIG. 8, this is a complementary Dual Carrier Field Effect Transistor Inverter with power supply of 0.65 volt. When C_{L}, C_{R} and G are used as input terminals, the output of this Three Dimensional Field Effect Transistor is NOR logic.

### EMBODIMENT 12

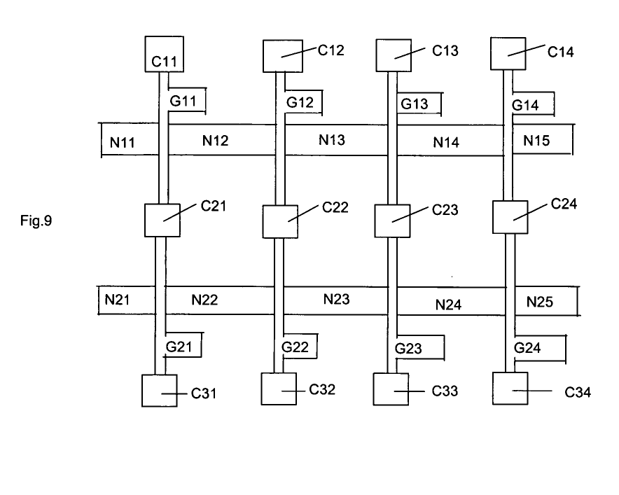

Referring to FIG. 9, this is a matrix lateral Dual Carrier Field Effect Transistor System-on-a-chip, or simply called lateral Three Dimensional Field Effect Transistor System-on-a-chip.

### INDUSTRIAL APPLICATION

This invention provides a completely new structure for two dimensional semiconductor field effect transistors to overcome the limitation due to lithographic techniques. By use of presently standard semiconductor processing technology, the effective channel length can be reduced to as short as 5 nm, the power supply voltage can be reduced to as low as 0.65 volt, and hence decrease the power consumption by a large amount and in the meantime improve its electrical performance. Two dimensional semiconductor field effect transistors with the said structure can be combined to form three dimensional field effect transistors where there are 3 to 12 channels in each transistor, system-on-a-chip in matrix form can be implemented with output current as high as 10 amperes. These can also be used to form complicated logic circuits, microwave circuits and linear circuits and enhance the implementation of system-on-a-chip. The field effect transistors with this new structure include both N channel Field Effect Transistors and P channel Field Effect Transistors, where both kinds of carriers, i.e. electrons and holes, exist simultaneously and both kinds of carriers contribute to the normal operation to form Dual Carrier Field Effect Transistors where there is no depletion of majority carriers in the channel region. By the said new structure, complementary inverters with both N channel Field Effect Transistors and P channel Field Effect Transistors can be implemented while system-on-a-chip with multiple Field Effect Transistors can also be implemented.

1. A type of Complementary Dual Carrier Field Effect Transistor, two semiconductor PN junctions (homo-junction or hetero-junction), corresponding to the source junction and the drain junction, are implemented on the substrate material, either perpendicular or parallel to the substrate surface, and three device terminals, the source terminal, the drain terminal and the contact terminal are made, with the distance from the contact terminal either to the source junction or to the drain junction being L_{z}, the distance between the source junction and the drain junction being Lₓ,
wherein: different doped regions ( N,P_{cc}, P_{ch}, P⁺) are implemented either along the direction perpendicular to the substrate surface or in different regions on the same surface of the substrate, whereby under the condition of high injection level and low voltage, a two dimensional potential distribution and electric field distribution and also a channel with narrow cross-sectional area being formed at z=L_{z}, along the edge between the source junction and the drain junction, close to the contact terminal and controlled by the contact terminal voltage.

2. The Complementary Dual Carrier Field Effect Transistor as in claim 1,
wherein: several layers of semiconductor material are implemented successively upon the substrate material, or several regions, each of different semiconductor material, are implemented on the same plane of the substrate material.

3. The Complementary Dual Carrier Field Effect Transistor as in claim 1 or claim 2,
wherein: on the insulating substrate, the first layer of semiconductor material being implemented forms the N⁺ doped region on which an ohmic contact terminal, i.e. the drain terminal D, is made, then the second layer of semiconductor material being implemented forms the second doped region, that is the doped region for the channel and in which the channel connection region is formed, the second layer of material being implemented also forms the P⁺ heavily doped region on which an ohmic contact terminal, i.e. the contact terminal C, is made, the third layer of semiconductor material being implemented forms the N⁺ doped region, on which an ohmic contact terminal, i.e. the source terminal S, is made.

4. The Complementary Dual Carrier Field Effect Transistor as in claim 1 or claim 2,
wherein: on top of the insulating substrate, the layers of semiconductor material being implemented are respectively: the P_{c} doped N channel region Ch, the P_{cc} doped channel connection region C.C., the P⁺ doped contact region, the N⁺ doped drain region, the N⁺ doped source region, also the ohmic contact terminal being made on the P⁺ doped contact region is the contact terminal C, the ohmic contact terminal being made on the N⁺ doped drain region is the drain terminal D, the ohmic contact terminal being made on the N⁺ doped source region is the source terminal S.

5. A Type of Complementary Dual Carrier Field Effect Transistor System-on-a-chip,
wherein: several layers of semiconductor material are being implemented on the substrate material to form complementary inverters with both N channel Field Effect Transistors and P channel Field Effect Transistors and to form matrix system-on-a-chip including more than two channels.

6. The complementary Dual Carrier field Effect Transistor System-on-a-chip as in claim 5,
wherein: lateral and vertical three dimensional and multi-channel transistor system-on-a-chip are being implemented through the combination of SOI Dual Carrier field Effect Transistors with Si MOS, or through the combination of multiple SOI vertical Dual Carrier Field Effect Transistors.

7. The Complementary Dual Carrier Field Effect Transistor System-on-a-chip as in claim 5 or claim 6,
wherein: this system-on-a-chip is a Complementary Dual Carrier Field Effect Transistor integrated circuit.
